(19) United States
(12) Patent Application Publication
(10) Pub. No.: US 2010/0109046 A1
(43) Pub. Date: May 6, 2010

(54) Methods of forming low interface resistance contacts and structures formed thereby

(76) Inventors: Rishabh Mehandru, Beaverton, OR (US); Bernhard Sell, Portland, OR (US); Anand Murthy, Portland, OR (US); Lucian Shifren, Hillsboro, OR (US)

Correspondence Address: Kathy J. Ortiz;c/o Intellevate, LLC, P.O. Box 52050, Minneapolis, MN, 55402, US

(21) Appl. No.: 12/290,809

(22) Filed: Nov. 3, 2008

(51) Int. Cl. H01L 29/778; H01L 21/336

(52) U.S. Cl. 257/190; 438/285; 257/E29.246; 257/E21.403

(57) ABSTRACT

Methods and associated structures of forming a microelectronic device are described. Those methods may include forming a tapered contact opening in an ILD disposed on a substrate, wherein a source/drain contact area is exposed, preamorphizing a portion of a source drain region of the substrate, implanting boron into the source/drain region through the tapered contact opening, forming a metal layer on the source/drain contact area, and then annealing the metal layer to form a metal silicide.

### BACK GROUND OF THE INVENTION

Contact to gate shorts become an increasingly difficult problem for integrated circuits with scaled dimensions. A gate process which forms a salicide through the contact hole may exhibit a high silicide interface resistance in some cases. Such a high suicide interface may produce a bottleneck when trying to improve the linear region and saturation region drive currents of the transistor device.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIGS. 1a-1e represent structures according to an embodiment of the present invention.

FIGS. 2a-2d represent graphs according to an embodiment of the present invention.

### DETAILED DESCRIPTION OF THE PRESENT INVENTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

Methods of forming microelectronic structures are described. Those methods may include Those methods may include forming a tapered contact opening in an ILD disposed on a substrate, wherein a source/drain contact area is exposed, preamorphizing a portion of a source drain region of the substrate, implanting boron into the source/drain region through the tapered contact opening, forming a metal layer on the source/drain contact area, and then annealing the metal layer to form a metal silicide. Methods of the present invention enable very low interface resistance contact at highly scaled pitch source/drain structures.

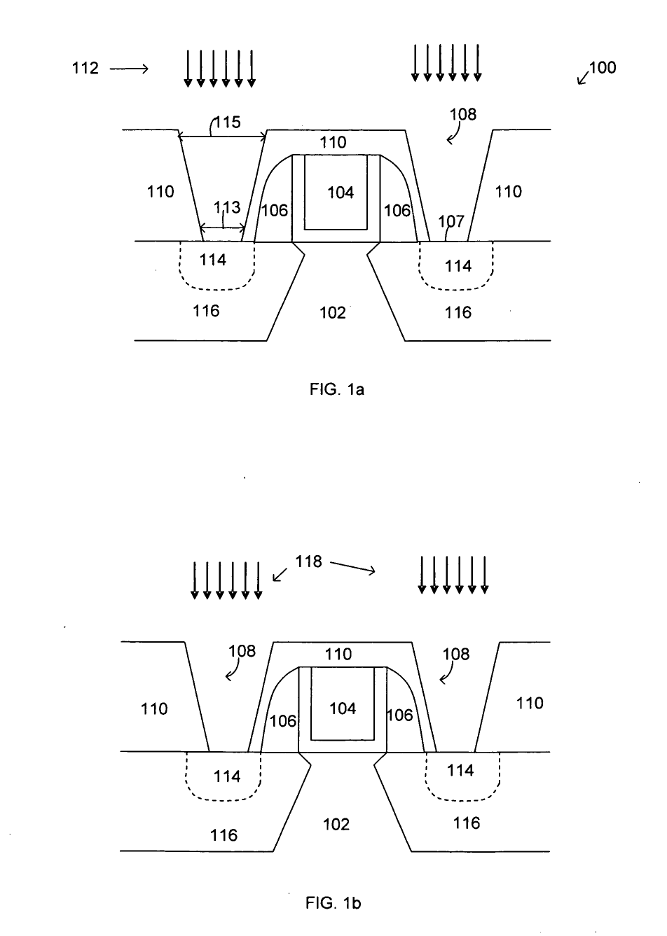

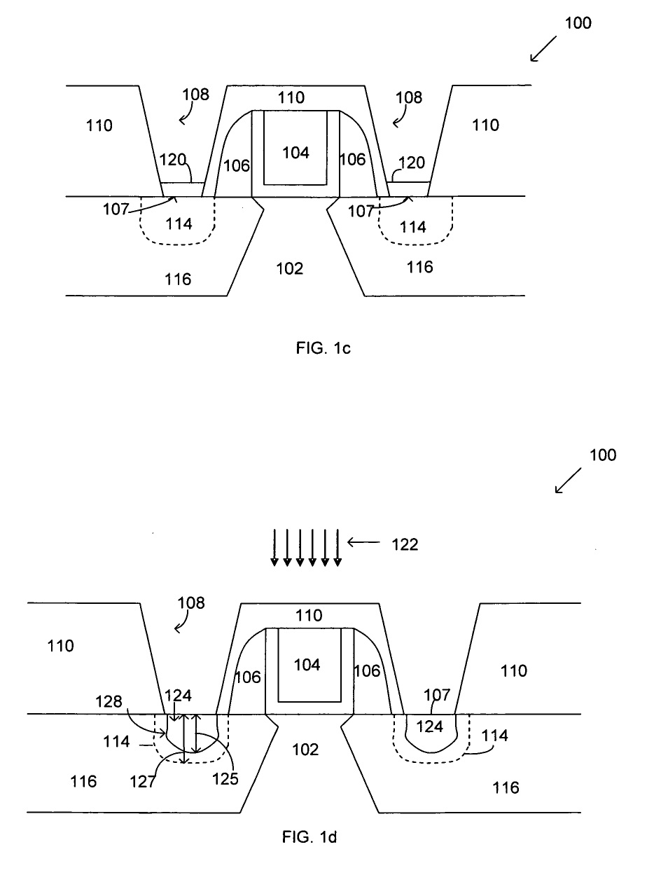

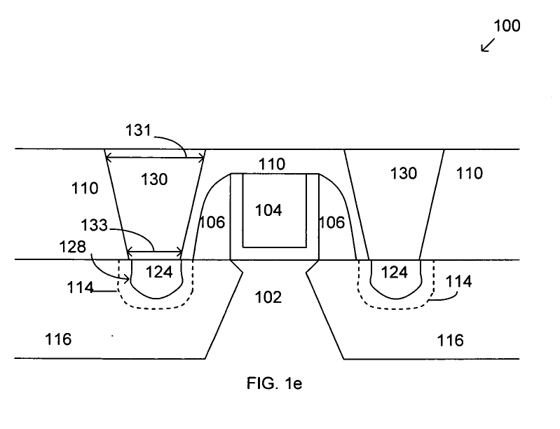

Methods of the present invention are depicted in FIGS. 1a-1e. FIG. 1a shows a cross section of a portion of a transistor structure 100 comprising a substrate 102, and a gate 104, which may comprise a metal gate in some embodiments, and may comprise such metal gate materials as hafnium, zirconium, titanium, tantalum, or aluminum, or combinations thereof, for example. The substrate 102 may be comprised of materials such as, but not limited to, silicon, silicon-on-insulator, germanium, indium antimonide, lead telluride, indium arsenide, indium phosphide, gallium arsenide, gallium antimonide, or combinations thereof. The substrate 102 may comprise a portion of a p-type metal oxide silicon (PMOS) transistor in some embodiments.

The transistor structure 100 may further comprise a spacer material 106, that may be adjacent to the gate 104. The spacer material 106 may comprise a dielectric material in some cases, such as but not limited to silicon dioxide and/or silicon nitride materials. The transistor structure 100 may further comprise a tapered contact opening 108, which may comprise an opening in an interlayer dielectric (ILD) 110. A nitride etch layer (nesl) may be removed during a previous process step (not shown) over a portion of a source/drain region(s) 116 of the substrate 102 by utilizing a nitride etching process, for example, so that a source/drain contact area 107 is exposed during the formation of the tapered contact opening 108. The tapered contact opening 108 may be adjacent to the gate 104, and may serve as an opening in which a contact metal may subsequently be formed. In an embodiment, the source/drain region 116 may comprise silicon germanium, and may comprise at least one of an epitiaxially grown silicon germanium and an implanted silicon germanium.

The tapered contact opening 108 may comprise a top portion width 115 that is larger than a bottom portion width 113. A preamorphizing implant 112 may be performed through the tapered contact opening 108, wherein a portion 114 of the source/drain region 116 may be made amorphous, and wherein the remaining portion of the source/drain region 116 may remain substantially crystalline in nature. In an embodiment, the preamorphization implant 112 may be performed using an implant species, such as but not limited to germanium.

Preamorphizing the portion 114 of the source/drain region 116 may prepare the portion 114 of the source/drain region for a subsequent silicide formation. A boron implant 118 may be performed through the tapered contact opening 108 after the preamorphizing implant 112 is performed, that may implant boron into the source/drain region 116 (FIG. 1b). In an embodiment, the boron implant 118 may be performed to increase the number of available boron dopant atoms into the source/drain region 116, including the amorphized portion 114 of the source/drain region 116. In an embodiment, the boron implant 118 may be substantially confined within the source/drain region 116.

The concentration of the boron implanted will depend upon the particular application, but may comprise a dose of about (5e14 and 1e16 ions/cm²) in some embodiments. In an embodiment, a metal layer 120, such as but not limited to a nickel layer, for example, may be formed on the source/drain contact area 107 (FIG. 1c). In an embodiment, the metal layer 120 may comprise any such metal that may form a silicide with the source/drain 116. In an embodiment, an anneal 122 may be performed on the transistor structure 100 (FIG. 1d). The anneal 122 may serve to form a silicide 124 that may form by a reaction between the metal layer 120 and the amorphized portion 114 of the source/drain region 116, and may form a nickel silicide, by illustration and not limitation. In an embodiment, because the metal 120 is formed through the tapered contact opening 108, the silicide may be substantially contained within the amorphized portion 114 of the source/drain region 116.

In an embodiment, the silicide 124 may be formed such that a depth 125 of the silicide 124 is shorter than a depth 127 of the amorphized portion 114 of the source/drain 116. In an embodiment, because the depth 125 of the silicide 124 may be targeted to be shorter than the depth 127 of the amorphized portion 114 of the source/drain 116, the formation of metal pipes, such as but not limited to nickel pipes, for example, may be avoided, thus reducing the risk of shorting failures in the transistor device structure 100. In an embodiment, active boron concentration at an interface 128 between the amorphized portion 114 of the source/drain 116 and the silicide 124 may be set by the anneal 122 processing conditions, such as the anneal temperature. In an embodiment, the anneal 122 temperature may comprise below about 600 degrees Celsius, but will depend upon the particular metal silicide 124 that may be formed.

In an embodiment, during the relatively low temperature of the anneal 122, solid phase epitaxial regrowth may occur within the amorphized portion 114 of the source/drain region 116. The amorphous region regrowth during the anneal 122 may serve to set the interphase dopant incorporation at solid phase regrowth. By implanting additional boron implanted atoms before the silicide 124 formation, a much higher substitutional boron incorporation at the silicide/amorphized portion interface 128 is possible.

Also, since the boron implant 118 may be performed such that the boron is located away from the tips (extensions) of the source/drain region 116, the risk of the boron implant overrunning the extensions is minimal. In an embodiment, the boron may comprise a higher concentration near the amorphous silicon/silicide interface 128 than at locations away from (non-interface portions) the interface 128. Thus, since additional boron atoms may be incorporated during the solid phase epitaxial regrowth of the amorphized portion 114 of the source/drain region 116, improved interface resistance may be realized. Additionally, in some embodiments, due to the lack of any high temperature thermal cycling after the boron implant, the implanted boron tends to remain within the source/drain regions 116.

In some prior art processes source/drain doping may occur during source/drain epitaxial deposition or by a boron self aligned implant after spacer formation, followed by a source/drain anneal. Both of these processes may leave lower active boron concentration at the silicide/amorphous interface, since the net amount of boron dopant atoms going past the silicide/amorphous silicon interface may be much lower, hence a much higher interface resistance may be encountered, especially if the silicide is made later in the process where the silicide area may be smaller. Attempts to increase boron doping by increasing the implant energy of self aligned implants may also results in source/drain extension regions being overrun with boron, thus increasing off state leakage and degrading the short channel effects.

In some prior art processes, wherein higher temperature anneals may be used, (such as when doping and then annealing the source/drain before pre-amorphization implant at 1000 degrees Celsius, for example), boron could be de-activated, which would cause a higher interface resistance leading to device failures. In contrast, implanting boron after the preamorphizing implant according to the various embodiments of the present invention, wherein the boron is then subjected to relatively lower temperature process of silicidation, improves boron incorporation and reduces interface resistance. The boron implant can become incorporated into substitutional sites within the amorphized region 114, which results in higher boron activation than with some prior art processes.

A contact metal 130 may be formed in the tapered contact opening 108 on the silicide 124 after it is annealed (FIG. 1e). The contact metal 130 may be tapered, wherein a top width 131 of the contact metal 130 may be larger than a bottom width 133 of the contact metal 130. In an embodiment, the contact metal 130 may comprise at least one of tungsten, titanium, titanium nitride and titanium tungsten. The silicide 124 may be coupled to the contact metal 130. The contact metal 130 may be formed by a process such as but not limited to chemical vapor deposition (CVD) process, for example.

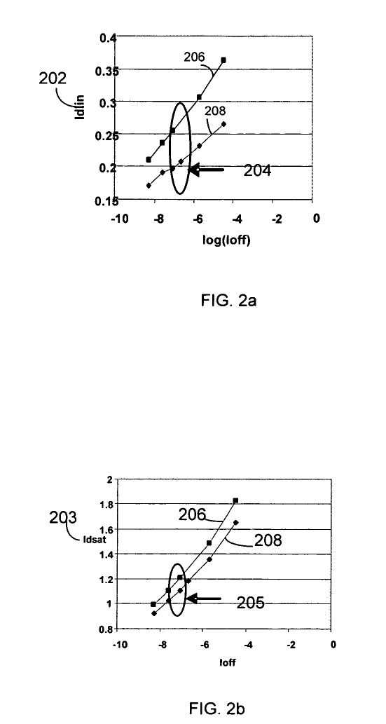

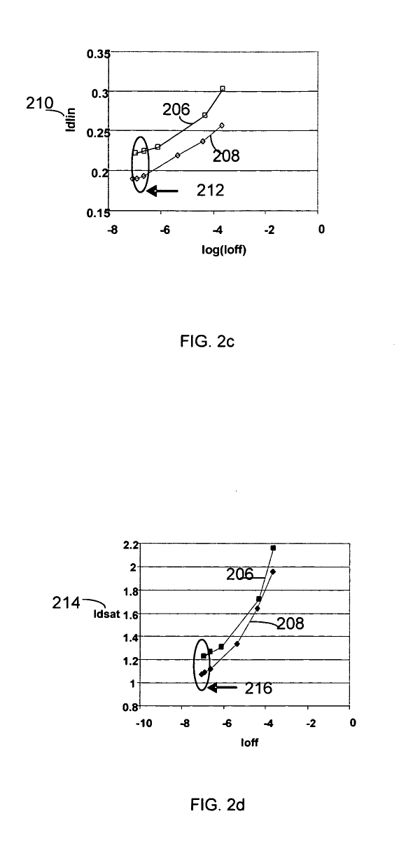

An advantage of the embodiments of the invention is that a very low interface resistance contact is possible, even at highly scaled pitch (very small source/drain openings). In an embodiment, a boron source/drain implant performed after a pre-amorphization implant (post tapered contact etch) and before a nickel deposition can boost linear drive current 202 (Idlin) by about 25 percent 204 (as compared to a prior art device 208) for a device fabricated according to embodiments of the present invention 206 (FIG. 2a). Such a device fabricated according to embodiments of the present invention 206 can improve saturation drive current 203 as well, by about 10 percent 205 (FIG. 2b) in some embodiments, at a matched off state current.

A linear drive current 210 improvement of about 13 percent 212 (FIG. 2c) and saturation drive current improvement 214 of about 11 percent 216 (FIG. 2d) may be achieved by a device fabricated according to embodiments of the present invention. was seen.

Methods of the present invention enable the fabrication of a transistor structure, such as a PMOS transistor, for example, with an additional implant done before a silicide formation through a tapered contact nitride etch stop layer etch. To enhance silicide formation, a pre amorphization implant may be done before metal deposition. Since the final silicide depth may be targeted to be shorter than the preamorphization depth to avoid metallic pipes, for example, active boron concentration at the silicide/amorphous interface may be set by a low temperature solid phase epitaxial regrowth process, as opposed to a higher anneal of 1000 degrees, as in the prior art. By implanting additional boron implant before silicide formation, much higher substitutional boron incorporation at the silicide/amorphous interface is possible. Since boron implant at this stage is much farther away from the source/drain extensions (tips), risk of the boron implant overrunning extensions is minimized.

Methods of the present invention improve the linear region and saturation region drive currents. By using a boron implant after a tapered contact etch and after silicide pre-amorphization implant, but before silicide metal deposition, a very low interface resistance between the amorphous semiconductor and the suicide contact can be achieved for a PMOS transistor. Since a lower energy boron implant can be used when implanting through the tapered contact region and due to the implant being farther distanced from the source/drain extensions, there is no increase in source/drain leakage or degradation in short channel effects. Net gain is a much higher on state current than for matched off state current.

Although the foregoing description has specified certain steps and materials that may be used in the method of the present invention, those skilled in the art will appreciate that many modifications and substitutions may be made. Accordingly, it is intended that all such modifications, alterations, substitutions and additions be considered to fall within the spirit and scope of the invention as defined by the appended claims. In addition, it is appreciated that certain aspects of microelectronic structures are well known in the art. Therefore, it is appreciated that the Figures provided herein illustrate only portions of exemplary microelectronic structures that pertain to the practice of the present invention. Thus the present invention is not limited to the structures described herein.

What is claimed is:

1. A method comprising:
forming a tapered contact opening in an ILD disposed on a substrate, wherein a source/drain contact area is exposed;
preamorphizing a portion of a source drain region of the substrate;
implanting boron into the source/drain region through the tapered contact opening;
forming a metal layer on the source/drain contact area; and
annealing the metal layer to form a metal silicide.

2. The method of claim 1 further comprising wherein the metal silicide comprises a depth that is shorter than a depth of the amorphized source/drain region.

3. The method of claim 1 further comprising wherein additional boron atoms are incorporated into the amorphized source/drain region.

4. The method of claim 1 wherein the concentration of boron is higher closer to a silicide/amorphous silicon interface.

5. The method of claim 1 further comprising wherein the substrate comprises a portion of a PMOS transistor.

6. The method of claim 1 further comprising wherein the substrate comprises a metal gate, and wherein the source/drain regions comprise silicon germanium.

7. The method of claim 6 further comprising wherein the silicon germanium source/drain regions are formed by at least one of epitaxial growth and implantation.

8. A method comprising:
forming a tapered contact opening in an IID;
removing a portion of a nesl to open a source/drain contact area on a PMOS substrate;
implanting a preamorphizing species through the tapered contact opening to amorphize a portion of a source/drain region of the substrate;
forming a metal on the source/drain contact area;
annealing the metal to form a metal silicide in the source/drain region; and
forming a contact metal in the contact opening;

9. The method of claim 8 further comprising wherein the annealing temperature is below about 600 degrees Celsius.

10. The method of claim 8 further comprising wherein the contact metal comprises a tapered contact metal.

11. The method of claim 10 further comprising wherein the contact metal comprises a bottom portion and a top portion, wherein the bottom portion comprises a smaller width than a diameter of the top portion.

12. The method of claim 8 further comprising wherein additional boron atoms are incorporated into the amorphized region during the annealing.

13. The method of claim 8 further comprising wherein the metal comprises nickel, and the metal silicide comprises a nickel silicide.

14. The method of claim 13 further comprising wherein the boron implant is targeted to be contained within the source/drain region.

15. A structure comprising:
a tapered contact metal disposed on a silicide disposed within a source/drain region of a substrate; and
a silicide/amorphous silicon interface disposed within the source/drain region, wherein a boron species comprises a higher concentration at the silicide/amorphous silicon interface of the source/drain region than in a non-interface portion of the source/drain region.

16. The structure of claim 15 wherein the source/drain region comprises silicon germanium.

17. The structure of claim 15 wherein the silicide comprises a nickel silicide.

18. The structure of claim 15 wherein the substrate comprises a portion of a PMOS device.

19. The structure of claim 15 wherein the tapered contact metal comprises a top portion and a bottom portion, wherein the bottom potion comprises a smaller width than a width of the top portion.

20. The structure of claim 15 wherein the source/drain region comprises an amorphized region and a non-amorphized region, and wherein the amorphized region is in contact with the silicide.

21. The structure of claim 20 wherein the silicide comprises a depth that is shorter than a depth of the amorphized source/drain region.

22. The structure of claim 15 wherein at least one of the tapered contact metal comprises at least one of tungsten, titanium, titanium nitride and titanium tungsten.

23. A structure comprising:
a gate disposed on a substrate;
a spacer material disposed adjacent the gate;
a tapered contact metal disposed on a silicide disposed in a source/drain region that is disposed in the substrate, wherein the tapered contact metal is disposed adjacent the gate; and
a silicide/amorphous silicon interface of the source/drain region, wherein a boron species comprises a higher concentration at the interface than in a non-interface portion of the source drain region.

24. The structure of claim 23 wherein the gate comprises a metal gate.

25. The structure of claim 23 wherein the tapered contact metal comprises at least one of tungsten, titanium, titanium nitride and titanium tungsten.

26. The structure of claim 23 wherein the contact metal comprises a top portion and a bottom portion, wherein the bottom potion comprises a smaller width than a width of the top portion.

27. The structure of claim 23 wherein the silicide is contained within the amorphized portion of the source/drain region.

28. The structure of claim 23 wherein the source/drain comprises a silicon germanium material.

29. The structure of claim 23 wherein the silicide comprises a nickel silicide.

30. The structure of claim 23 wherein the substrate comprises a portion of a PMOS transistor.
